(19) United States
(12) Patent Application Publication
(10) Pub. No.: US 2024/0170310 A1
(43) Pub. Date: May 23, 2024

(54) SUBSTRATE PROCESSING APPARATUS, METHOD OF MANUFACTURING SEMICONDUCTOR DEVICE, AND RECORDING MEDIUM

(71) Applicant: Kokusai Electric Corporation, Tokyo (JP)

(72) Inventors: Tomoki MATSUNAGA, Toyama-shi (JP); Masahito Kitamura, Toyama-shi (JP); Hiroyuki Kitamoto, Toyama-shi (JP); Takafumi Nitta, Toyama-shi (JP)

(73) Assignee: Kokusai Electric Corporation, Tokyo (JP)

(21) Appl. No.: 18/430,763

(22) Filed: Feb. 2, 2024

Related U.S. Application Data
(63) Continuation of application No. PCT/JP2021/028641, filed on Aug. 2, 2021.

(51) Int. Cl. H01L 21/67; H01L 21/02

(52) U.S. Cl. CPC H01L 21/67253; H01L 21/02271; H01L 21/67098; H01L 21/6719

(57) ABSTRACT

To enable improvement in uniformity of film thickness between a plurality of substrates as compared with that of the related art in a case where the plurality of substrates is loaded in a boat and subjected to batch processing, a substrate processing apparatus is configured to include a process container capable of accommodating a substrate holder that holds substrates, a gas supplier that supplies a gas to the process container, an exhauster that exhausts an atmosphere in the process container, a transporter that transports the substrates, and a controller configured to be capable of controlling the transporter to dispersedly load the substrates from a central portion of a first region in a case where a number X of the substrates is smaller than a maximum loading number Y of the substrate holder, and the substrate holder includes, at the central portion, the first region where the dispersion loading is performed.

### CROSS-REFERENCE TO RELATED APPLICATION

This application is a Bypass Continuation Application of PCT International Application No. PCT/JP2021/028641, filed on Aug. 2, 2021, the entire contents of which are incorporated herein by reference.

### BACKGROUND

### Field

The present disclosure relates to a substrate processing apparatus, a method of manufacturing a semiconductor device, and a recording medium.

### Description of the Related Art

As one of the processes of manufacturing a semiconductor device (device), processing of forming a film on a substrate accommodated in a process chamber may be performed.

### SUMMARY

According to one or more embodiments of the present disclosure, there is provided a technique that including: a process container capable of accommodating a substrate holder that holds substrates, a gas supplier that supplies a gas to the process container, an exhauster that exhausts an atmosphere in the process container, a transporter that transports the substrate, and a controller configured to be capable of controlling the transporter to dispersedly load the substrates from a central portion of a first region in a case where a number X of the substrates is smaller than a maximum loading number Y of the substrate holder, and the substrate holder includes, at the central portion, the first region where the dispersion loading is performed.

### BRIEF DESCRIPTION OF THE DRAWINGS

FIG. 1 is a schematic configuration diagram of a process furnace of a substrate processing apparatus suitably used in an embodiment of the present disclosure, and is a diagram illustrating a process furnace portion in a longitudinal sectional view.

FIG. 2 is a cross-sectional view taken along line A-A of FIG. 1.

FIG. 3 is a B-B arrow view of FIG. 2.

FIG. 4 is a block diagram illustrating a configuration of a controller included in the substrate processing apparatus illustrated in FIG. 1.

FIG. 5 is a flowchart illustrating a substrate processing process according to an embodiment of the present disclosure.

FIG. 6 is a front view of a boat in a state in which substrates are mounted on the boat according to an embodiment of the present disclosure.

FIG. 7 is a front view of a boat in another state in which substrates are mounted on the boat according to an embodiment of the present disclosure.

FIGS. 8A and 8B are graphs illustrating a distribution of a gas exposure amount for substrates loaded in a boat according to an embodiment of the present disclosure.

FIG. 9 is a front view of a gas pipe in which gas supply holes are uniformly formed as a reference example for the configuration illustrated in FIG. 3.

### DETAILED DESCRIPTION

With the recent increase in the degree of integration and three-dimensional structure of semiconductor devices in recent years, there has been an increasing number of cases where a substrate having a pattern formed on its surface by a laminate (assembly) of predetermined layers or films is processed.

In a case where a batch processing apparatus that processes a plurality of substrates that is loaded simultaneously on a boat processes large surface area substrates less than the maximum loadable (processable) number are while being loaded in a substrate holder (boat) in which a plurality of substrates is loaded, it is general to load the substrates together in one region of the substrate holder (boat) to simplify a substrate transport pattern and shorten a transport time.

For example, in a case where 25 substrates are processed by a vertical batch processing apparatus capable of collectively processing 100 substrates using a substrate holder (boat), 25 substrates are loaded from the top stage sequentially to the lower stage of the substrate holder, or 25 substrates are loaded from the bottom stage sequentially to the upper stage, or 25 substrates are loaded sequentially in the vicinity of the central portion of the substrate holder. In that case, the film thicknesses around slots in which the substrates are loaded may be thinner than that around slots in which no substrate is loaded.

That is, in the region, of the substrate holder (boat), in which 100 substrates are loaded, the film thickness varies depending on the location where the substrates are loaded, so that the inter-surface film thickness uniformity of the loading regions deteriorates. Furthermore, in the 25 substrates loaded sequentially, the film thickness of the film formed on the substrate loaded at the central portion is thin compared to the film thickness of the film formed on the substrate loaded at the end among the 25 substrates. That is, there is an issue that uniformity of film characteristics (for example, film thickness) of the substrates in 25 substrates loaded sequentially is deteriorated.

In addition, the total surface area of the groups of the substrates varies depending on the surface area of the substrates and the number of loaded substrates, so that the total surface area of the groups of substrates loaded varies between batches. Accordingly, the average film thickness of the film formed on the substrate varies between batches, and even if the same number of cycles of alternately supplying a plurality of process gases under the same process conditions are performed, the average film thickness of the film formed on the substrate varies among the positions where the substrates are loaded in the substrate holder (boat). As described above, when the substrates are loaded in the substrate holder (boat) and processed, it may be difficult to control the film thickness between the substrates. The substrate means a substrate (product substrate) on which a device (semiconductor device) is formed. On the product substrate, various patterns (a plurality of irregularities) formed in the process of forming the semiconductor device are formed. Due to the patterns, the product substrate has a larger surface area than that of a substrate on which no pattern is formed.

The present disclosure solves the above-described issues, and in a case where less than the maximum loadable number of substrates are loaded in the substrate holder (boat), the substrates are dispersedly loaded in the slots of the substrate holder (dispersion charging), so that also for films formed on the substrates loaded in any slots, desired film characteristics (for example, film thickness) uniformity can be achieved.

An embodiment of the present disclosure will be described in detail below based on the drawings. In all drawings for describing the embodiment of the present disclosure, components having the same functions are denoted with the same reference signs and thus duplicate description thereof will be omitted in principle. The drawings used in the following description are all schematic, and thus, dimensional relationships between elements, ratios between elements, and the like illustrated in the drawings do not necessarily coincide with realities. In addition, a dimensional relationship between elements, a ratio between the elements, and the like do not necessarily coincide also between the plurality of drawings.

Note that the present disclosure is not construed as being limited to the contents described in the following embodiment. It is obvious to those skilled in the art that the specific configurations can be modified without departing from the idea or spirit of the present disclosure.

### Example

In the example described below, an example will be described in which in a case where the number of the substrates on which a batch processing is performed is smaller than the maximum number of substrates loaded in the boat, the substrates are loaded such that the density of the substrates loaded in a region farther from the center is higher than a region closer to the center in the processing region of the boat. With such a configuration, a difference between the exposure amount of a process gas (at least one of a raw material gas and a reaction gas) to the substrates in a region closer to the center of the boat and the exposure amount of the process gas to the substrates in a portion farther from the center of the boat can be reduced, and thus the processing uniformity of the substrates in the boat can be improved. In the present disclosure, the “exposure amount” means the exposure amount of the process gas to the substrate. It also means the amount of gas contributing to formation of a film. In the present disclosure, the “process gas” may mean at least one or more of a raw material gas and a reaction gas. That is, the “exposure amount” means the exposure amount of the raw material gas, the exposure amount of the reaction gas, or the exposure amount of the raw material gas and the reaction gas.

That is, in the example described below, an example will be described in which the density of the substrates loaded in a region including the central portion of the boat is made sparser than the density of the substrate loaded in a portion farther from the central portion. With this configuration, the difference between the exposure amount of the process gas to the substrates loaded in the region including the central portion and the exposure amount of the process gas to the substrates loaded in a portion farther from the central portion can be reduced.

In addition, in the example described below, an example will be described in which the density of the substrates loaded in a region including the central portion of the boat is made sparser than the density of the substrate loaded in a portion farther from the central portion, and dummy substrates are loaded between the substrates. With this configuration, the difference between the exposure amount of the process gas to the substrates sparsely loaded in the region including the central portion and the exposure amount of the process gas to the substrates densely loaded in a portion farther from the central portion can be reduced. Here, the dummy substrate may be a substrate having a surface area smaller than that of the product substrate, and may be a substrate on which no pattern is formed or a substrate on which a pattern is formed. Preferably, the dummy substrate is a substrate on which a pattern is formed and which has a surface area smaller than that of the product substrate. In the present disclosure, the dummy substrate is referred to as a small area substrate.

### (1) Configuration of Substrate Processing Apparatus

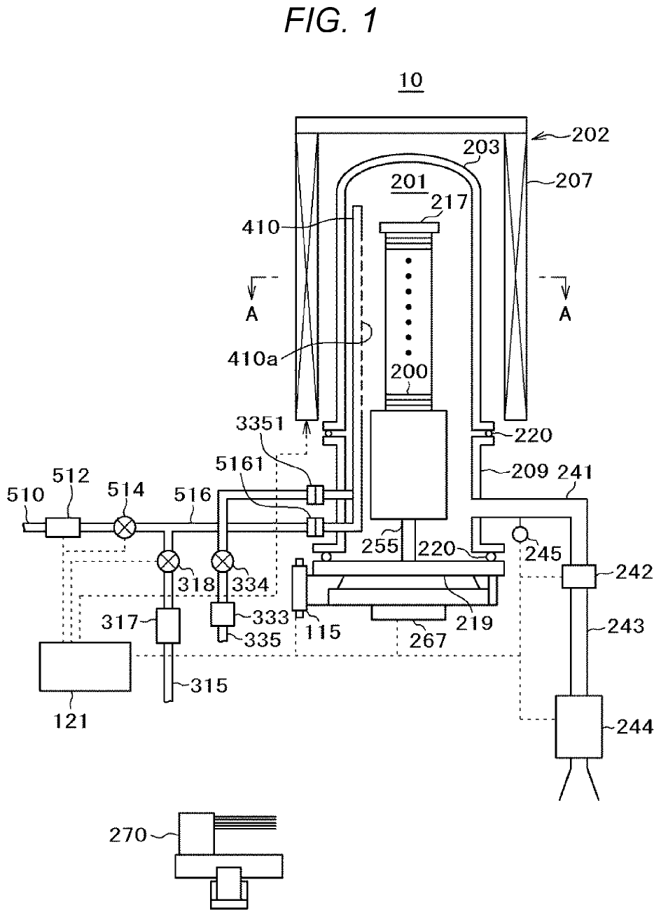

The configuration of a substrate processing apparatus 10 will be described with reference to FIGS. 1 to 4.

As illustrated in FIG. 1, the substrate processing apparatus 10 includes a process furnace 202 provided with a heater 207 serving as a heating means (heating mechanism, heating system). The heater 207 has a cylindrical shape, and is vertically installed by being supported by a heater base (not illustrated) serving as a holding plate.

Inside the heater 207, a reaction tube 203 is disposed concentrically with the heater 207. The reaction tube 203 is made of, for example, a heat-resistant material such as quartz (SiO2) or silicon carbide (SiC), and is formed in a cylindrical shape with an upper end closed and a lower end opened. A manifold 209 is disposed below the reaction tube 203 concentrically with the reaction tube 203. The manifold 209 is made of metal, for example, stainless steel (SUS) or the like, and is formed in a cylindrical shape having an upper end a lower end opened.

An O-ring 220 serving as a seal member is provided between the upper end of the manifold 209 and the reaction tube 203. The manifold 209 is supported by a heater base, and thus, the reaction tube 203 is installed vertically to the heater 207. A process container (reaction container) mainly includes the reaction tube 203 and the manifold 209. A process chamber 201 is formed in a cylindrical hollow portion of the process container. The process chamber 201 can accommodate wafers 200 serving as substrates in a state where the wafers 200 are arranged in multiple stages in the vertical direction in a horizontal posture by a boat 217 described later.

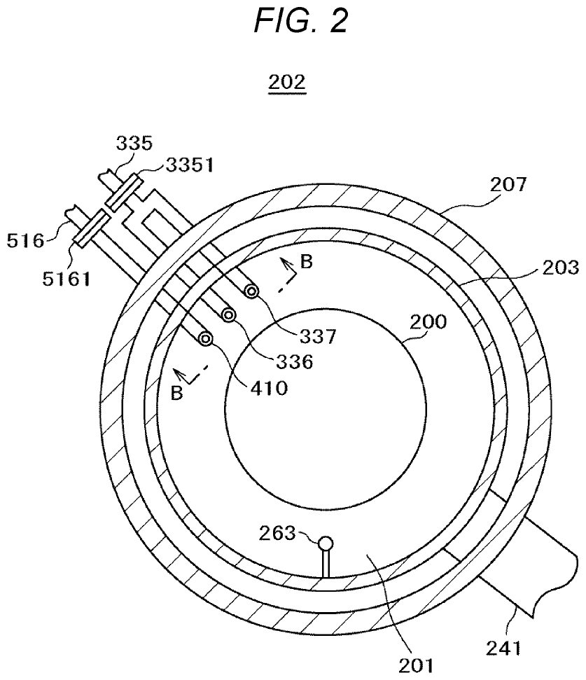

In the process chamber 201, nozzles 410, 336, and 337 (see FIG. 2) are provided to penetrate the side wall of the manifold 209. To the nozzle 410, a gas supply pipe 516 is, and to the nozzles 336 and 337, a gas supply pipe 335 is connected. The gas supply pipes 335 and 516 function as gas supply lines. The gas supply lines may be considered to include the nozzles 410, 336, and 337. The process furnace 202 of the present embodiment is not limited to the above-described form. The number of nozzles and the like is appropriately changed as necessary.

An exhaust pipe 241 serving as an exhaust flow passage that exhausts an atmosphere inside the process chamber 201 is provided in the reaction tube 203. A pressure sensor 245 serving as a pressure detector that detects a pressure in the process chamber 201 and an auto pressure controller (APC) valve 242 serving as an exhaust valve (pressure adjuster) are connected to the exhaust pipe 241.

The APC valve 242 is connected to a vacuum pump 244 via an exhaust pipe 243. The APC valve 242 is configured to be capable of opening and close a valve, with the vacuum pump 244 in operation, to vacuum-exhaust and stop vacuum-exhausting the process chamber 201, and further configured to be capable of adjusting a degree of valve opening based on pressure information detected by the pressure sensor 245, with the vacuum pump 244 in operation, to adjust the pressure in the process chamber 201. An exhaust system mainly includes the exhaust pipes 241 and 243, the APC valve 242, and the pressure sensor 245. The vacuum pump 244 may be included in the exhaust system.

An exhauster in the present disclosure includes at least the exhaust pipe 241. The pressure adjuster may be a part of the exhauster.

A seal cap 219 serving as a furnace lid that is capable of hermetically closing a lower end opening of the manifold 209 is provided below the manifold 209. The O-ring 220 serving as a seal member in contact with the lower end of the manifold 209 is provided on the upper surface of the seal cap 219. On a side of the seal cap 219 opposite to the process chamber 201, a rotation mechanism 267 that rotates the boat 217 described later is disposed.

A rotation shaft 255 of the rotation mechanism 267 penetrates the seal cap 219 and is connected to the boat 217, and is configured to rotate the wafer 200 by rotating the boat 217. The seal cap 219 is configured to be raised and lowered in the vertical direction by a boat elevator 115 serving as a raising/lowering mechanism vertically disposed outside the reaction tube 203.

The boat elevator 115 is configured to be capable of carrying in the boat 217 in the process chamber 201 and carrying out the boat 217 from the process chamber 201 by raising and lowering the seal cap 219. The boat elevator 115 is configured as a transport device (transport mechanism) that transports the boat 217, that is, the wafer 200 to the inside and the outside of the process chamber 201.

The boat 217 serving as a substrate support is configured to support a plurality of, for example, 25 to 200 wafers 200 in multiple stages while the wafers 200 are aligned in the vertical direction in a horizontal posture in a state where the centers are aligned with each other, that is, to load (arrange, place) the wafers 200 at intervals. The boat 217 is made of, for example, a heat-resistant material such as quartz or SiC.

Included is a substrate transporter (transfer machine) 270 serving as a transporter that is provided outside the process chamber 201 and transports, for example, 1 to 5 wafers 200 from a front opening unify pod (FOUP) (not illustrated) to a substrate support.

FIG. 2 illustrates an A-A cross section of the reaction tube 203 and the heater 207 in FIG. 1. As illustrated in FIG. 2, a temperature sensor 263 serving as a temperature detector is installed in the reaction tube 203. By adjusting the degree of energization to the heater 207 based on temperature information detected by the temperature sensor 263, a desired temperature distribution can be achieved in the process chamber 201. The temperature sensor 263 is formed in an L shape similarly to the nozzles 410, 336, and 337 and is disposed along an inner wall of the reaction tube 203.

A raw material gas used for processing in the inside of the process chamber 201 passes through a gas supply pipe 510 from a raw material gas supply source (not illustrated), passes through a valve 514 for turning on and off a flow of gas in a state where a flow rate is adjusted through a mass flow controller (MFC) 512 together with a carrier gas (inert gas) supplied from a carrier gas supply source (not illustrated), and is supplied to the inside of the process chamber 201 from the nozzle 410 connected by a joint 5161 through the gas supply pipe 516.

In addition, the reaction gas that reacts with the raw material gas inside the process chamber 201 passes through a gas supply pipe 315 from a reaction gas supply source (not illustrated), passes through a valve 318 for turning on and off a flow of gas in a state where a flow rate is adjusted through a mass flow controller (MFC) 317 together with the carrier gas (inert gas) supplied from the carrier gas supply source (not illustrated), and is supplied to the inside of the process chamber 201 from the nozzle 410 connected by the joint 5161 through the gas supply pipe 516. At this time, the valve 514 on the raw material gas side is in an off state so that only the reaction gas flows inside the gas supply pipe 516.

On the other hand, an inert gas such as nitrogen (N₂) is supplied to the gas supply pipe 335 from an inert gas supply source (not illustrated), passes through a valve 334 for turning on and off a flow of the gas in a state where a flow rate is adjusted through a mass flow controller (MFC) 333, passes through a joint 3351, and then branches to be supplied from the nozzles 336 and 337 to the inside of the process chamber 201.

As illustrated in FIG. 1, the nozzle 410 is configured as an L-shaped nozzle and is provided such that the horizontal portion penetrates the side wall of the manifold 209 and the reaction tube 203. As illustrated in FIG. 2, a vertical portion of the nozzle 410 is provided in an annular space between the reaction tube 203 and the wafer 200 in a plan view to erect upward and extend in the loading direction of the wafer 200, along the inner wall of the reaction tube 203 from the lower portion to the upper portion. The nozzles 336 and 337 are also provided in a shape similar to the nozzle 410.

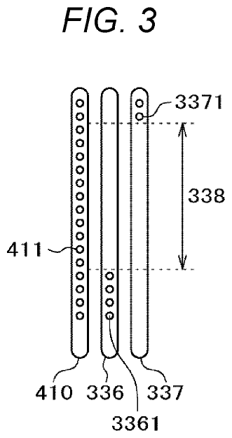

In the configuration illustrated in FIG. 1, at heights corresponding to the wafers 200 loaded in the boat 217 on the side surfaces of the nozzles 410, 336, and 337 (heights corresponding to the loading region of the wafers 200), a plurality of gas supply holes 411 for supplying gas is formed at equal pitches on the side of a surface 410a facing the boat 217 as illustrated in FIG. 3 (B-B arrow view of FIG. 2). On the other hand, in the nozzle 336, a plurality of gas supply holes 3361 in the lower portion is formed, and in the nozzle 337, a plurality of gas supply holes 3371 is formed in the upper portion.

In the present example, the inert gas is supplied to the inside of the reaction tube 203 using the nozzle 336 in which the plurality of gas supply holes 3361 is formed in the lower portion and the nozzle 337 in which the plurality of gas supply holes 3371 less than the gas supply holes 3361 is formed in the upper portion.

Here, an example has been described in which the number of the gas supply holes 3361 is larger than that of the gas supply holes 3371. However, the number of holes may be reversed. In addition, here, an example has been described in which the gas supply holes are formed in a circular shape. However, the gas supply holes may be formed in a slit shape or a rectangular shape. When the gas supply holes are formed to have the slit shape, the length of the slits is appropriately adjusted. Preferably, the upper end of the gas supply holes 3361 is set lower than a processing region 338. In addition, preferably, the lower end of the gas supply holes 3371 is set higher than the processing region 338.

With this configuration, the process gas (at least one of the raw material gas and the reaction gas) supplied to the processing region 338 is diffused to the outside of the processing region 338, so that the concentration of the gas supplied to each of wafers 600 at the positions corresponding to the processing region 338 can be uniformized. In other words, dilution of the gas can be suppressed in at least one of the upper end and the lower end of the processing region 338. The number of the gas supply holes 3361 and the number of the gas supply holes 3371 are appropriately set according to the concentration of the gas supplied to the wafers 600 on the upper end side and the lower end side of the processing region 338. The processing region 338 corresponds to a region where the wafers 600 as product wafers are loaded in the boat 217.

A gas supplier in the present disclosure includes at least any of the gas supply pipes. Specifically, the gas supplier in the present disclosure includes at least one of the gas supply pipe 510 through which the raw material gas flows and the gas supply pipe 315 through which the reaction gas flows.

In the configuration illustrated in FIG. 3, a plurality of the gas supply holes 411 of the nozzle 410 is provided from the lower portion to the upper portion of the reaction tube 203, each have the same opening area, and are provided at the same opening pitches to correspond to the wafers 200 loaded in the boat 217. However, the gas supply holes 411 are not limited to the above-described form. For example, the opening area may be gradually increased from the lower portion (upstream side) to the upper portion (downstream side) of the nozzle 410. As a result, flow rates of the gas supplied through the gas supply holes 411 can be uniformized.

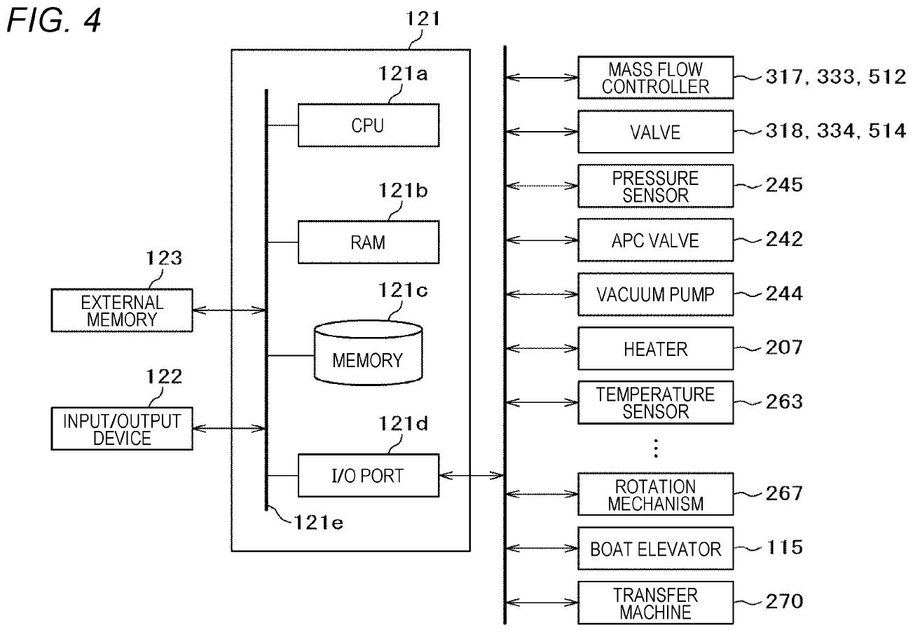

As illustrated in FIG. 4, a controller 121 serving as a controller (control means) is configured as a computer including a central processing unit (CPU) 121a, a random access memory (RAM) 121b, a memory 121c, and an I/O port 121d. The RAM 121b, the memory 121c, and the I/O port 121d are configured to be capable of exchanging data with the CPU 121a via an internal bus 121e. An input/output device 122 or an external memory 123 configured as, for example, a touch panel or the like is connected to the controller 121.

The memory 121c includes, for example, a flash memory, a hard disk drive (HDD), or the like. A control program for controlling an operation of the substrate processing apparatus, a process recipe in which procedures, conditions, and the like of substrate processing described later are described, and the like are readably stored in the memory 121c.

The process recipes are combined to cause the controller 121 to execute procedures in film formation process described later to obtain a predetermined result, and functions as a program. Hereinafter, the process recipe, the control program, and the like are also collectively and simply referred to as a program. In addition, the process recipe is also simply referred to as a recipe.

When the term “program” is used in the present specification, it may include only a single process recipe, may include only a single control program, or may include a combination thereof depending on the case. The RAM 121b is configured as a memory area (work area) in which the program, data, and the like read by the CPU 121a are temporarily stored.

The I/O port 121d is connected to the MFCs 317, 333, and 512, the pressure sensor 245, the APC valve 242, the vacuum pump 244, the temperature sensor 263, the heater 207, the rotation mechanism 267, the boat elevator 115, the transfer machine 270, and the like described above.

The CPU 121a is configured to read the control program from the memory 121c and execute the control program, and to read the recipe from the memory 121c in response to an input or the like of an operation command from the input/output device 122.

The CPU 121a is configured to be capable of controlling, in accordance with the content of the read recipe, flow rate adjusting operations of various gases by the MFCs 317, 333, and 512, opening/closing operations of the valves 318, 334, and 514, an opening/closing operation of the APC valve 242, a pressure adjusting operation by the APC valve 242 based on the pressure sensor 245, start and stop of the vacuum pump 244, a temperature adjusting operation of the heater 207 based on the temperature sensor 263, a rotating operation and a rotation speed adjusting operation of the boat 217 by the rotation mechanism 267, a raising/lowering operation of the boat 217 by the boat elevator 115, a substrate transport operation of the transfer machine 270, and the like.

The controller 121 can be configured by installing the above-described program stored in the external memory (for example, a magnetic tape, a magnetic disk such as a flexible disk or a hard disk, an optical disk such as a CD or a DVD, a magneto-optical disk such as an MO disk, or a semiconductor memory such as a USB memory or a memory card) 123 in a computer.

The memory 121c and the external memory 123 are each configured as a computer-readable recording medium. Hereinafter, the memory 121c and the external memory 123 are collectively and simply referred to as a recording medium. When the term “recording medium” is used in the present specification, it may include only a single memory 121c, may include only a single external memory 123, or may include both of them depending on the case. The program may be provided to the computer not using the external memory 123 but using a communication means such as the Internet or a dedicated line.

### (2) Substrate Processing Process (Film Formation Process)

An example process of forming a nitride film on a substrate will be described as one of the processes of manufacturing a semiconductor device (device) using the substrate processing apparatus described with reference to FIGS. 1 to 4. The process of forming the nitride film on the substrate is performed using the process furnace 202 of the substrate processing apparatus 10 described above. In the following description, operations of the units constituting the substrate processing apparatus 10 are controlled by the controller 121.

In the present specification, the term “wafer” may mean “a wafer itself” or “a laminate (assembly) of a wafer and a predetermined layer, film, or the like formed on a surface of the wafer” (that is, a wafer with a predetermined layer, film, or the like formed on a surface of the wafer is referred to as a wafer). In the present specification, the term “surface of a wafer” may mean “a surface (exposed surface) of a wafer itself” or “a surface of a predetermined layer, film, or the like formed on a wafer, that is, an outermost surface of a wafer as a laminate”. In the present specification, the term “substrate” is synonymous with the term “wafer”.

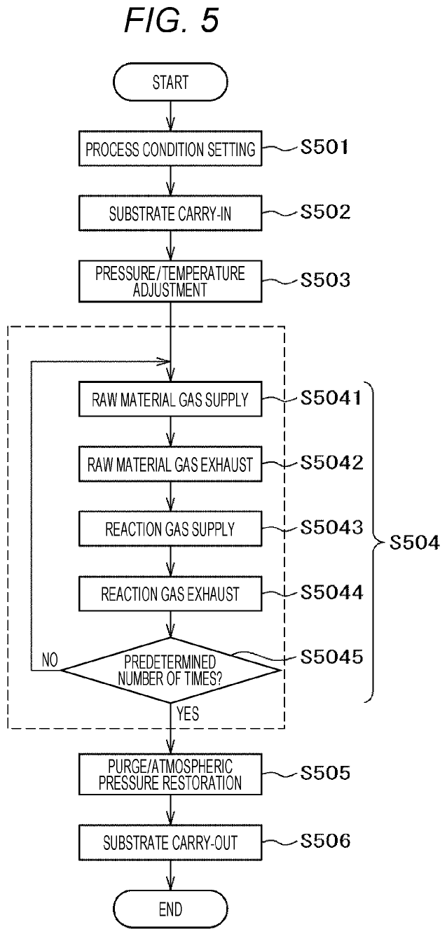

Hereinafter, a method of manufacturing a semiconductor device according to the present embodiment will be described in detail with reference to the flowchart illustrated in FIG. 5.

(Process Condition Setting): S501

First, the CPU 121a of the controller 121 reads the process recipe and a related database stored in the memory 121c to set a process condition. Here, at least one or more pieces of data indicating the sizes of a region 610 (611) serving as the first region and region 620 (621) serving as the second region, and the data of the boat loading pattern, which will be described later, are read from the memory 121c, and one or both of the sizes of the regions and the boat loading pattern are set based on at least the number of wafers 600 loaded in the boat 217. Specifically, the sizes of the regions may be data indicating the sizes, or may be the data of the numbers of the wafers 600 loaded in the regions.

(Wafer Carry-In): S502

The transfer machine 270 loads a plurality of wafers 200 to be processed by the process recipe in the boat 217.

The plurality of wafers 200 is carried in (boatload) into the process chamber 201. Specifically, the transfer machine 270 is controlled based on the data of the boat loading pattern corresponding to the plurality of wafers 200 (wafers 600 as product substrates and dummy wafers 602) to load (wafer charge) the plurality of wafers 200 in the boat 217. After the wafers 200 are loaded in the boat 217, as illustrated in FIG. 1, the boat 217 supporting the plurality of wafers 200 is lifted by the boat elevator 115 and is carried in the process chamber 201. In this state, the seal cap 219 is in a state of airtightly closing a lower end opening of the reaction tube 203 via the O-ring 220.

(Pressure/Temperature Adjustment): S503

The process chamber 201 is vacuum-exhausted by the vacuum pump 244 to have a desired pressure (degree of vacuum) in its inside. At this time, the pressure in the process chamber 201 is measured by the pressure sensor 245, and the APC valve 242 is feedback-controlled (pressure adjustment) based on the measured pressure information. The vacuum pump 244 maintains a state of being constantly operated at least until the processing on the wafers 200 is completed.

The inside of the process chamber 201 is heated by the heater 207 to have a predetermined temperature (For example, 200˜ 800° C.). At this time, an energization amount to the heater 207 is feedback-controlled based on temperature information detected by the temperature sensor 263 such that the inside of the process chamber 201 has a predetermined temperature distribution (temperature adjustment). The inside of the process chamber 201 is sequentially heated by the heater 207 at least until processing on the wafers 200 is completed.

(Film Formation Step): S504

Thereafter, a raw material gas supply step, a residual gas removal step, a reaction gas supply step, and a residual gas removal step are performed a predetermined number of times in this order.

(Raw Material Gas Supply Step): S5041

The valve 514 is opened to cause HCDS (hexachlorodisilane) gas to flow from the gas supply pipe 510 to the gas supply pipe 516. The flow rate of the HCDS gas is adjusted by an MFC 512, and the HCDS gas is supplied to the wafers 200 from the gas supply holes 411 opening in the nozzle 410. That is, the wafers 200 are exposed to the HCDS gas. The HCDS gas supplied from the gas supply holes 411 is exhausted from the exhaust pipe 241. At this time, the valve 334 is simultaneously opened to allow N₂ gas to flow from the gas supply pipe 335 as an inert gas. The flow rate of the N₂ gas is adjusted by the MFC 333, and the N₂ gas is supplied from the gas supply holes 3361 of the nozzle 336 to the lower portion side of the process chamber 201 and from the gas supply holes 3371 of the nozzle 337 to the upper portion side of the process chamber 201, and is exhausted from the exhaust pipe 241.

At this time, the APC valve 242 is appropriately adjusted to set a pressure in the process chamber 201 to a pressure in a range of, for example, 1 to 1330 Pa, preferably 10 to 931 Pa, and more preferably 20 to 399 Pa. When the pressure is higher than 1330 Pa, purging may not be sufficiently performed, and a by-product may be incorporated into a film to increase resistance. When the pressure is lower than 1 Pa, the reaction speed of HCDS may not be obtained. In the present specification, for example, 1 to 1000 Pa as a range of numerical value means 1 Pa or more and 1000 Pa or less. That is, 1 Pa and 1000 Pa are included in the range of numerical value. The same applies to all numerical values described herein, such as flow rate, time, temperature, as well as pressure.

The supply flow rate of the HCDS gas controlled by the MFC 512 is in a range of, for example, 0.01 to 10 slm and preferably 0.1 to 5.0 slm.

The N₂ gas serving as a carrier gas is also supplied from the nozzle 410 to the inside of the process chamber 201 through the gas supply pipe 516 with the flow rate adjusted by an MFC (not illustrated), and the supply flow rate of the N₂ gas is in a range of, for example, 0 to 49 slm, preferably 0 to 19.3 slm, and more preferably 0 to 9.5 slm so as to be in a range of, for example, 0.01 to 50 slm, preferably 0.1 to 20 slm, and more preferably 0.2 to 10 slm. When the total flow rate is more than 50 slm, there is a possibility that the gas is adiabatically expanded and re-liquefied at the gas supply holes 411. When the supply flow rate of the HCDS gas is small with respect to the desired throughput, preferably, the supply flow rate of the N₂ gas is increased. In addition, making the N₂ gas to flow is also effective in improving the uniformity of the HCDS gas supplied from the gas supply holes 411.

The time for supplying the HCDS gas to the wafers 200 is in a range of, for example, 1 to 300 seconds, preferably 1 to 60 seconds, and more preferably 1 to 10 seconds. The time longer than 300 seconds may deteriorate the throughput and increase the running cost, and the time shorter than 1 second may result in the exposure amount less than that required for film formation.

By supplying the HCDS gas to the process chamber 201 under the above-described condition, a Si-containing layer is formed on an outermost surface of the wafers 200.

(Raw Material Gas Exhaust Step): S5042

After the Si-containing layer is formed, the valve 514 is closed to stop the supply of the HCDS gas. At this time, the process chamber 201 is vacuum-exhausted by the vacuum pump 244 with the APC valve 242 kept opened, and the HCDS gas remaining inside the process chamber 201 and not having reacted or having contributed to formation of the Si-containing layer is removed from the inside of the process chamber 201. The valve 334 is opened to maintain the supply of the N₂ gas to the process chamber 201. The N₂ gas acts as a purge gas and can enhance an effect of removing, from the process chamber 201, the HCDS gas remaining inside the process chamber 201 and not having reacted or having contributed to formation of the Si-containing layer.

(Reaction Gas Supply Step): S5043

After the residual gas in the process chamber 201 is removed, the valve 318 is opened to cause an NH₃ gas that is a reaction gas to flow into the gas supply pipe 315. The flow rate of the NH₃ gas is adjusted by the MFC 317, and the NH₃ gas is supplied from the gas supply holes 411 of the nozzle 410 to the wafers 200 inside the process chamber 201, and is exhausted from the exhaust pipe 241. That is, the wafers 200 are exposed to the NH₃ gas. The flow rate of the N₂ gas serving as a carrier gas is also adjusted by an MFC (not illustrated), then passes through the gas supply pipe 315 to be supplied together with the NH₃ gas from the nozzle 410 to the process chamber 201, and is exhausted from the exhaust pipe 241.

At this time, as an inert gas that has been flow-rate-regulated by the MFC 333, the N₂ gas is simultaneously supplied from the gas supply holes 3361 of the nozzle 336 to the lower portion side of the process chamber 201 through the gas supply pipe 335 and from the gas supply holes 3371 of the nozzle 337 to the upper portion side of the process chamber 201, and is exhausted from the exhaust pipe 241.

At this time, the APC valve 242 is appropriately adjusted to set a pressure in the process chamber 201 to a pressure in a range of, for example, 1 to 13300 Pa, preferably 10 to 2660 Pa, and more preferably 20 to 1330 Pa. The pressure higher than 13300 Pa may require time to perform the residual gas removal step described later, deteriorating the throughput, and the pressure lower than 1 Pa may result in an exposure amount less than that required for film formation.

The supply flow rate of the NH₃ gas controlled by the MFC 317 is in a range of, for example, 1 to 50 slm, preferably 3 to 20 slm, and more preferably 5 to 10 slm. The supply flow rate more than 50 slm may require time to perform the residual gas removal step described later, deteriorating the throughput, and the supply flow rate less than 1 slm may result in an exposure amount less than that required for film formation.

The supply flow rate of the N₂ gas supplied as a carrier gas is a flow rate in a range of, for example, 0 to 49 slm, preferably 0 to 17 slm, and more preferably 0 to 9.5 slm so as to be a flow rate in a range of, for example, 1 to 50 slm, preferably 3 to 20 slm, and more preferably 5 to 10 slm. The total flow rate more than 50 slm may require time to perform the residual gas removal step described later, deteriorating the throughput, and the total flow rate less than 1 slm may result in an exposure amount less than that required for film formation.

The time for supplying the NH₃ gas to the wafers 200 is in a range of, for example, 1 to 120 seconds, preferably 5 to 60 seconds, and more preferably 5 to 10 seconds. The time longer than 120 seconds may deteriorate the throughput and increase the running cost, and the time shorter than 1 second may result in an exposure amount less than that required for film formation. The other processing conditions are similar to those in the above-described raw material supply step.

At this time, the gases flowing in the process chamber 201 are only the NH₃ gas and the inert gas (N₂ gas). The NH₃ gas reacts with at least a part of the Si-containing layer formed on the wafers 200 in the raw material gas supply step to form a silicon nitride layer (SiN layer) containing Si and N. That is, the Si-containing layer is modified into the SiN layer.

(Reaction Gas Exhaust Step): S5044

After the SiN layer is formed, the valve 318 is closed to stop the supply of the NH₃ gas. Then, in a processing procedure similar to the residual gas removal step after the raw material gas supply step, the NH₃ gas not having reacted or having contributed to formation of the SiN layer and a reaction by-product remaining inside the process chamber 201 are removed from the process chamber 201 while maintaining the supply of the N₂ gas to the process chamber 201 with the valve 334 open.

(Predetermined Number of Times of Performance): S5045

A SiN film is formed on the wafers 200 by performing one or more (predetermined number of times) cycles of sequentially performing the raw material gas supply step, the residual gas removal step, the reaction gas supply step, and the residual gas supply step described above. The number of performing this cycle is appropriately selected according to the film thickness required in the SiN film to be finally formed, but this cycle is preferably repeated a plurality of times.

(Purge/Atmospheric Pressure Restoration): S505

After completion of the film formation step, the valve 334 is opened to supply the N₂ gas to the process chamber 201 from the gas supply pipe 335 and exhaust the gas from the exhaust pipe 241. The N₂ gas acts as a purge gas to remove a gas or a by-product remaining in the process chamber 201 from the process chamber 201 (after-purge). Thereafter, the atmosphere in the process chamber 201 is replaced with the N₂ gas (N₂ gas replacement), so that the pressure in the process chamber 201 is restored to a normal pressure (atmospheric pressure restoration).

(Substrate Carry-Out): S506

Thereafter, the seal cap 219 is lowered by the boat elevator 115 to open the lower end of a manifold 209, and the processed wafers 200 are carried out (boat unload) from the lower end of the manifold 209 to the outside of the reaction tube 203 in a state of being supported by the boat 217. After the boat-unload, a shutter 219s is moved to seal the lower end opening of the manifold 209 by the shutter 219s through the O-ring 220c (shutter close). After being unloaded to the outside of the reaction tube 203, the processed wafers 200 are carried out from the boat 217 (wafer discharge).

### (3) Substrate Loading

Subsequently, dispersion loading of the wafers 200 into the boat 217 performed prior to the film formation process will be described.

In the present example, the dispersion loading refers to an action of intentionally leaving at least one slot or more without the wafers 200 loaded between the wafers 200, dividing the wafers 200, and dividing the loading slots of the wafers 200 into at least two or more and loading the divided loading slots, instead of disposing all the wafers 200 sequentially in the slots of the boat 217 when the plurality of wafers 200 is loaded into the boat 217. Each of groups obtained by dividing the wafers 200 is referred to as a wafer group. In the wafer group, groups may be sequentially loaded into loading slots. In addition, the lower limit number of the wafers in the wafer group may be one.

In the present example, in a case where the boat 217 has the loading region (slot) for Y (Y≥3) wafers and less than Y wafers 200 are loaded in the boat 217 and processed, the wafers 200 are dispersedly loaded. As a result, the distribution of loading density of the wafers 200 in slots of the wafer loading region is flattened to improve the inter-surface film thickness uniformity.

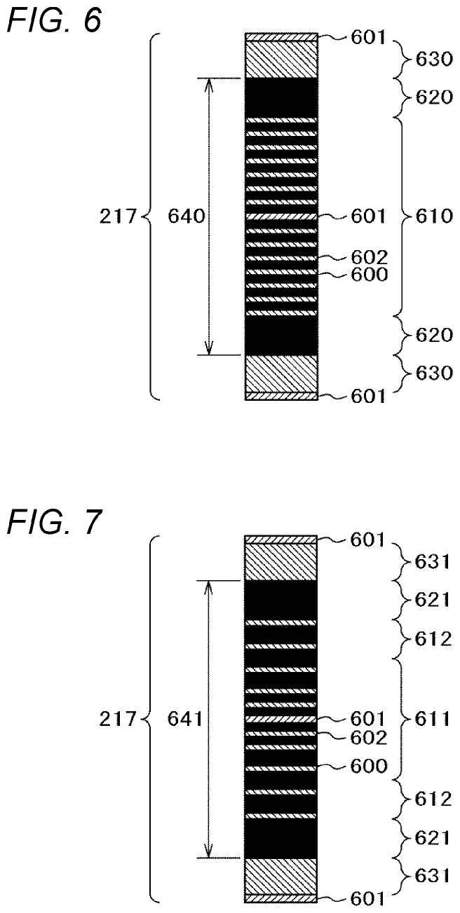

A specific example of the present example will be described with reference to FIGS. 6 to 8. First, a case where the film characteristics of each wafer 200 are improved by the dispersion loading of the wafers 200 will be described. The film characteristics are, for example, film thickness, film quality, and the like.

FIG. 6 illustrates an example in which in the boat 217 having the loading region for 100 wafers, the wafers 600 (corresponding to the wafers 200 in FIGS. 1 and 2) are dispersedly loaded by loading the wafers 600 into two divided regions 610 and 620 having different loading pitches (intervals between the wafers 600). Monitor substrates 601 that monitor the film thicknesses of the films formed on substrates are loaded at both upper and lower ends and a central portion of the boat 217. The region 610 corresponds to the first region of the present disclosure, and the region 620 correspond to the second region of the present disclosure. In addition, the monitor substrates 601 and the dummy wafer 602 are not necessarily provided. When the dummy wafer 602 is used, the number of dummy wafers 602 is set according to the number of product substrates (wafers 600) loaded in the region 610 serving as the first region. The number of dummy wafers 602 is set to be the same as the number of slots in which the wafers 600 are not loaded among the slots of the region 610. In FIG. 6, a processing region 640 corresponds to the region 610 serving as the first region and the region 620 serving as the second region.

In FIG. 6, in the region 610, the monitor substrate 601 is loaded in the central portion of the boat 217, the wafers 600 to be processed are loaded on both sides thereof, and the dummy wafers 602 and the wafers 600 are alternately loaded on the outer sides thereof. In addition, in the region 620 close to the end portions of the boat 217 outside the region 610 (upper and lower portions of the region 610), the wafers 600 are sequentially loaded without using the dummy wafers 602. Furthermore, in the region 630 between the region 620 and the place where the monitor substrates 601 are loaded at the ends of the boat 217, only the dummy wafers 602 are loaded without loading any wafer 600. The sizes of the regions (region 610, region 620, and region 630) are set according to the total number of the wafers 600 loaded in the boat 217.

The position of the region 610 is set to be at a central portion of the substrate support (processing region 640). The size of the region 610 is set according to the number X of the wafers 600 as product substrates. Specifically, when the number X is small, the size of the region 610 is set to be large, and when the number X is large, the size of the region 610 is set to be small. That is, the size of the first region (region 610) where the dispersion loading is performed is set according to the number X of wafers 600. The size of the region 620 serving as the second region is relatively changed in accordance with the size of the region 610 serving as the first region. That is, the size ratio between the region 610 serving as the first region and the region 620 serving as the second region is set based on the relationship between X and Y.

Data indicating the relationship between X and Y is stored in table data recorded in the memory 121c. For example, when the total number X (X is an integer) of the wafers 600 as product substrates is equal to the maximum number Y (Y is an integer) of the wafers 600 loaded in the boat 217 (the maximum loading number), the region 610 is not set. When X is close to Y, the size of the region 610 serving as the first region is smaller than that of the region 620 serving as the second region. That is, the region where the wafers 600 are dispersedly loaded is configured to be smaller than the region where the wafers 600 are sequentially loaded. When X is about a half of Y, the size of the region 610 serving as the first region is configured to be larger than the size of the region 620 serving as the second region. That is, the region where the wafers 600 are dispersedly loaded is configured to be larger than the region where the wafers 600 are sequentially loaded.

Here, the relationship between the size of the region 610 and the number of wafers 600 to be loaded is experimentally obtained and determined such that the uniformity of processing of the wafers 600 is improved, for example. Table data indicating the optimum relationship between the size of the region 610 and the number of wafers 600 is recorded in the memory 121c to be described later. The size of the region 610 is set, for example, when the number of wafers 600 to be processed is determined. Specifically, the size of the region 610 is set when the process recipe to be executed next is read from the memory 121c (for example, in a process of process condition setting S501 to be described later). The relationship between the sizes of the region 620 and the number of wafers 600 may also be experimentally obtained and determined such that the uniformity of processing of the wafers 600 is improved, and table data indicating the relationship between the sizes of the region 620 and the number of wafers 600 may be recorded in the memory 121c. Table data indicating the relationship between the number of wafers 600, the size of each region (the region 610 and the region 620), and the boat loading pattern is recorded in the memory 121c and is read from the memory 121c in the process condition setting process S501.

FIG. 7 illustrates an example in which the wafers 600 are dispersedly loaded in the boat 217 having the loading region for 100 wafers while being divided into three regions 611, 612, and 621 having different loading pitches (intervals between the wafers 600). The region 611 corresponds to the first region, and the region 621 corresponds to the second region. The region 612 may be set as a part of the first region, or may be set as a third region other than the first region. Similarly to the case of FIG. 6, the monitor substrates 601 for monitoring the film thicknesses of the films formed on substrates may be loaded at both upper and lower ends and a central portion of the boat 217. A processing region 641 in FIG. 7 corresponds to the region 611 serving as the first region, the region 621 serving as the second region, and the region 612 serving as the third region.

In FIG. 7, in the region 611, the monitor substrate 601 is loaded in the central portion of the boat 217, the wafers 600 to be processed are loaded on both sides thereof, and the dummy wafers 602 and the wafers 600 are alternately loaded on the outer sides thereof. In addition, there are the regions 612, 621, and 631 in the regions outside the region 611. In each of the region 612, the region in which two or more wafers 600 are sequentially loaded and the region in which one dummy wafer 602 is loaded are alternately provided. In the region 621, the wafers 600 are sequentially loaded outside the region 612 without using the dummy wafer 602. Further, in the region 631 between the region 621 and the place where the monitor substrate 601 is loaded at the end of the boat 217, only the dummy wafers 602 are loaded without loading the wafers 600.

As described above, the boat is configured such that the loading density of the wafers 600 in the regions (regions 611 and 612) where the dispersion loading is performed gradually vary. Here, an example in which two regions where the dispersion loading is performed are provided has been described, but the present disclosure is not limited thereto, and three or more regions may be provided.

By loading the wafers 600 such that the loading density of the wafers 600 in the boat 217 gradually changes, it is possible to reduce the difference in the exposure amounts of the process gas to the wafers 600. That is, the processing uniformity for the wafers 600 can be improved. The size of each region (region 611, region 612, and region 631) is determined according to the total number of wafers 600 loaded in the boat 217.

Here, an example in which the wafers 600 and the dummy wafers 602 are alternately disposed in the region 611 has been described, but the present disclosure is not limited thereto, and one wafer 600 and a plurality of dummy wafers 602 may be alternately disposed so that the density of the wafers 600 in the region 611 is smaller than the density of the wafers 600 in other regions. Here, the plurality of dummy wafers 602 is sequentially loaded between the wafers 600. The number of the dummy wafers 602 sequentially loaded is set based on the number of the wafers 600 loaded in the boat 217. The number of dummy wafers 602 sequentially loaded between the wafers 600 may be, for example, 2 or 3. The interval between the wafers 600 can be widened by the number of dummy wafers 602. In other words, the loading density of the wafers 600 can be reduced.

As described above, by making the density of the wafers 600 in the central portion of the boat 217 smaller than the density of the wafers 600 on the outer sides of the boat 217, the exposure amount of the process gas to the wafers 600 loaded in the central portion of the boat 217 can be increased. Here, an example in which the dummy wafers 602 are loaded in the region 611 has been described, but the present disclosure is not limited thereto, and the dummy wafers 602 are not necessarily loaded. Loading the dummy wafers 602 allows the gas exposure amount of the process gas for the wafers to be uniformized. In the vicinity of the slot in which a dummy wafer 602 is not loaded, the gas consumed by the dummy wafer 602 is supplied to another wafer 600, so that the exposure amount of the gas to the wafers 600 in the vicinity of the slot in which the dummy wafers 602 is not loaded can be increased. When the increase in the exposure amount is large, the exposure amount can be uniformized by loading the dummy wafers 602. The dummy wafers 602 having different surface areas may be loaded. Loading the dummy wafers 602 having different surface areas allows the exposure amount of the gas to the wafers 600 to be adjusted. Specific slots may be designated as the positions where the dummy wafers 602 having different surface areas are loaded, or the positions where the dummy wafers 602 having different surface areas may be selected according to the interval between the wafers 600.

The loading pitch of the wafers 600 is set by the number X of the wafers 600. Table data indicating the relationship between the number of wafers 600 and the loading pitch (interval between the wafers 600) is recorded in the memory 121c. The loading pitch data corresponding to the number X of wafers 600 is read from the table data of the memory 121c and set.

As illustrated in FIG. 7, the pattern in which the wafers 600 are loaded at different loading pitches is suitably used in a case where the number X of the wafers 600 is, for example, half or less of the maximum loading number Y, and preferably about a dozen. In a case where the number of processed wafers 600 is small, adopting such an arrangement pattern can improve processing uniformity for the wafers 600.

Here, the number of wafers 600 to be loaded in the region 611 and the number of wafers 600 to be loaded in the region 612 and the region 621 are experimentally obtained and determined to improve uniformity of processing between the wafers 600 in the regions, and are readably recorded in the memory 121c as corresponding table data.

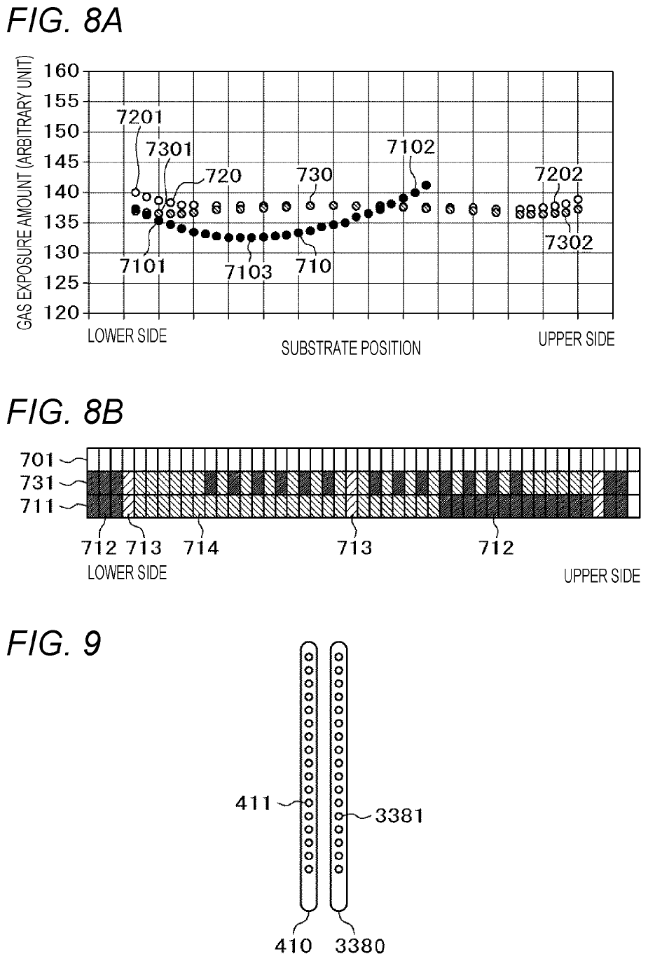

The distribution of the exposure amounts of the raw material gas (and the reaction gas) to the wafers 600 depending on the loading positions of the wafers 600 into the boat 217 in a case where the wafers 600 are loaded in the boat 217 and films are formed on the wafers 600 by the procedure described in the above-described “(2) film formation process” as illustrated in FIG. 6 or 7 is illustrated in 730 of FIG. 8A.

In FIG. 8A, the horizontal axis indicates the loading positions of the wafers 200 (the wafers 600 of FIGS. 6 and 7) in the slots of a boat 701 (corresponding to the boat 217 in FIG. 1, FIG. 6, and FIG. 7) schematically illustrated in FIG. 8B, and indicates the wafer loading positions in ascending order from the bottom to the top. In the boat 701 of FIG. 8B, the right side corresponds to the upper side of the boat 217 illustrated in FIG. 6 or FIG. 7, and the left side of the boat 701 of FIG. 8B corresponds to the lower side of the boat 217 illustrated in FIG. 6 or FIG. 7.

In FIG. 8A, the vertical axis indicates the exposure amount of the process gas to each wafer loaded in the boat 701. In other words, the vertical axis means the amount of gas contributing to the formation of a film on each wafer. A larger numerical value on the vertical axis indicates a larger exposure amount of the process gas to the wafer 600, and a smaller numerical value on the vertical axis indicates a smaller exposure amount of the process gas to the wafer 600. In addition, a larger exposure amount of the gas means a larger thickness of a film formed on the wafer 600. A smaller exposure amount of the gas means a smaller thickness of a film formed on the wafer 600. Here, the exposure amount of the gas in FIG. 8A mainly means the exposure amount of the raw material gas serving as the process gas, but it is estimated that the exposure amount of the reaction gas has a similar tendency. That is, the difference in the exposure amounts of the process gas causes an issue that at least the film thickness among the film characteristics varies for the wafers 600. In addition, the difference between the exposure amounts of the raw material gas and the exposure amounts of the reaction gas may cause an issue that the film composition varies for the wafers 600.

Data 730 in FIG. 8A illustrates a gas exposure amount distribution for the wafers loaded in the boat 701 according to the present example. The data 730 indicates the gas exposure amount distribution according to the present example in which the wafer loading region in the boat 701 is formed to include a region in the vicinity of the central portion in which the wafers are loaded in every other slot and a region outside thereof in which the wafers are loaded adjacent to each other as illustrated as 731 of FIG. 8B corresponding to the loading of the wafers 200 in the boat 217 described in FIG. 6. In addition, the raw material gas, the reaction gas, and the inert gas are supplied to the process chamber 201 using the nozzles 410, 336, and 337 as illustrated in FIG. 3.

In the graph illustrated in FIG. 8A, as a first comparative example with respect to the data 730 of the gas exposure amount distribution according to the present example, data 710 indicates the distribution of the exposure amount of the process gas to the wafers at positions in a case where the wafers are loaded adjacent to each other in a region 714 as illustrated in a boat loading arrangement diagram 711 of the wafer of FIG. 8B. In the boat loading arrangement diagram 711 of the wafer of FIG. 8B, a reference numeral 713 denotes a position where a dummy wafer for monitoring a film thickness is loaded.

In a case where all the wafers 200 are simply loaded sequentially as illustrated in the boat loading arrangement diagram 711 of the wafer of FIG. 8B, as illustrated in the data 710 of FIG. 8A, a difference in the exposure amount of the process gas in peripheral portions 7101 and 7102 with respect to the exposure amount of the process gas in the vicinity of a central portion 7103 is large. That is, as illustrated as the data 710 of the comparative example, it can be seen that the distribution of the exposure amount of the process gas depending on the loaded positions is large in a case where all the wafers are loaded adjacent to each other in the boat. Specifically, the exposure amount in the vicinity of the central portion decreases and the exposure amount at the peripheral portions 7101 and 7102 increases. The reason is considered that, since no wafer 600 exists above the peripheral portion 7102, the gas that would be consumed in the vicinity of the peripheral portion 7102 is supplied to the wafers in the peripheral portion 7102. The same applies to the peripheral portion 7101. On the other hand, the density of the wafers 600 is high in the vicinity of the central portion 7103 and thus the gas consumed by the wafers 600 is larger. Therefore, it is considered that the gas exposure amount supplied to the wafers 600 is lower.

In addition, data 720 in FIG. 8A illustrates a second comparative example with respect to the data 730 of the gas exposure amount distribution according to the present example. In the second comparative example, similarly to the case of the present example described with reference to FIG. 6, the wafers are loaded in every other slot in the vicinity of the central portion of the boat 701, and the wafers are loaded adjacent to each other in the vicinity of the peripheral portions of the boat 701 as illustrated in a boat loading arrangement diagram (boat loading pattern) 731 of the wafer of FIG. 8B. However, in the second comparative example, instead of the nozzles 336 and 337 which are gas supply pipes in the present example illustrated in FIG. 3, an inert gas (N₂ gas) of the same type as a carrier gas is supplied using a gas supply pipe 3380 in which a large number of gas supply holes 3381 as illustrated in FIG. 9 are formed at equal pitches from top to bottom. The data of the boat loading pattern is recorded in the memory 121c.

That is, in the second comparative example, illustrated is the distribution of the exposure amount of the process gas to the wafers at the positions in a case where films are formed while the inert gas is supplied substantially uniformly in the vertical direction using the gas supply pipe 3380 for supplying the inert gas in which a large number of the gas supply holes 3381 are formed at equal pitches.

As illustrated in the data 720 of the second comparative example illustrated in FIG. 8A, the distribution of the exposure amount of the process gas is improved as compared with the data 710 of the first comparative example. That is, by loading the wafers as in the boat loading arrangement diagram 731, the distribution of the gas exposure amount to the wafers can be improved. Even in the boat loading arrangement diagram 731, there is still a difference in the exposure amount of the process gas between both end portions 7201 and 7202 and the vicinity of the central portion.

On the other hand, in the data 730 of the gas exposure amount distribution according to the present example illustrated in FIG. 8A, a difference in the exposure amount of the process gas between both end portions 7301 and 7302 and the vicinity of the central portion is further smaller than that in the case of the data 720 of the second comparative example, and the distribution of the exposure amount of the process gas between the wafers is improved.

In the present example, as illustrated in FIG. 3, the nozzle 336 serving as a second nozzle and the nozzle 337 serving as a first nozzle are used as supply pipes for an inert gas, and the gas supply holes 3361 serving as second supply holes are formed on the lower side of the nozzle 336, and the gas supply holes 3371 serving as first supply holes are formed on the upper side of the nozzle 337.

With such a configuration, the amount of the inert gas supplied to the wafers 200 loaded in the upper portion and the lower portion of the boat 217 with respect to the amount of the inert gas supplied to the wafers 200 loaded in the vicinity of the central portion of the boat 217 is more than the inert gas (carrier gas) components contained in the raw material gas or the reaction gas supplied from the gas supply holes 411 of the nozzle 410.

As a result, as illustrated in the data 710 of the first comparative example and the data 720 of the second comparative example in FIG. 8A, the difference of the exposure amount of the process gas to the wafers loaded in the upper and lower peripheral portions from that to the wafers loaded in the central portion of the boat 217 is suppressed, and the distribution of the exposure amount of the process gas between the wafers is improved.

Although not illustrated in the graph of FIG. 8, even in the case of loading the wafers such that the control density of the wafers 200 gradually increases s from the portion close to the central portion of the boat 217 toward the outside as described with reference to FIG. 7, by supplying the raw material gas, the reaction gas, and the inert gas using the nozzles 410, 336, and 337 as illustrated in FIG. 3, the distribution of the exposure amount of the process gas between the wafers similar to the data 730 of the gas exposure amount distribution of FIG. 8A is obtained, and the distribution of the exposure amount of the process gas between the wafers is improved as compared with the first and second comparative examples.

As described above, according to the present disclosure, in a case where substrates are subjected to batch processing, uniformity of film thicknesses of the plurality of substrates can be improved as compared with that of the related art. In addition, controllability of the film thickness of a film formed on the substrate can be improved.

In the above-described embodiment, as the inert gas, a rare gas such as Ar gas, He gas, Ne gas, and Xe gas may be used instead of the N₂ gas.

In the above-described embodiment, the nozzle 410 is shared for the supply of the raw material gas and the supply of the reaction gas to the process chamber 201. However, the nozzle for supplying the raw material gas and the nozzle for supplying the reaction gas may be separated.

In the above-described embodiment, the configuration has been described in which the inert gas is supplied from the nozzle 336 and the nozzle 337 in FIG. 3. However, the nozzle 336 and the nozzle 337 may be configured to be capable of supplying, instead of the inert gas, at least one of the raw material gas and the reaction gas. By supplying at least one of the raw material gas and the reaction gas from the nozzle 336 and the nozzle 337, the film thickness of the film to be formed on the wafers 600 loaded in at least one of the upper side and the lower side of the boat can be larger.

In the above-described embodiment, an example in which one or both of the wafers 600 and the dummy wafers 602 are loaded in all the slots of the boat 217 has been mainly described, but the present disclosure is not limited thereto. Depending on the configuration of the substrate processing apparatus, the process recipe (substrate processing condition), and the like, film characteristics formed on the wafers 600 loaded in specific slots of the boat 217 may be significantly worse than film characteristics formed on the wafers 600 loaded in other slots. For example, the gas exposure amount illustrated in FIG. 8A may be different from that in other slots. In such a case, the specific slots may be set to be slots in which the wafers 600 are not loaded, so that the wafers 600 are not loaded in the specific slots regardless of the number of the wafers 600. Here, the configuration of the substrate processing apparatus is the shape of a nozzle that supplies a gas, the shape and positions of supply holes formed in the nozzle, the position of the exhaust pipe 241, and the like. The process recipe is a characteristic of the gas to be supplied, a supply timing, a processing temperature, a pressure, a flow rate of the gas, and the like. In addition, there is a possibility of being affected by a pattern formed on the surface of the wafer 600.

In the above-described embodiment, the silicon nitride film (SiN) has been exemplified and described as a film formed on the wafer 600, but the present disclosure is not limited thereto. For example, the present disclosure can also be applied to a process of forming a film containing at least one or more of elements such as Si, Ge, Al, Ga, In, Ti, Zr, Hf, La, Ta, Mo, and W. In addition, in the above-described embodiment, an example in which a nitride film is formed has been described, but the present disclosure is not limited thereto. For example, a film containing at least one of oxygen (O), carbon (C), and nitrogen (N) or a single-element film not containing these elements may be used.

In the above-described embodiment, an example has been described in which a silicon nitride film serving as an insulating film is formed as one of the processes of manufacturing a semiconductor device, but the present disclosure can be applied not only to the semiconductor device, but also a film forming process (substrate processing) that is one process of manufacturing processes of various devices such as a display device, a light emitting device, a light receiving device, and a solar cell device.

It is preferable that a recipe (a program in which processing procedures, processing conditions, and the like are described) used for the film formation processing and the cleaning processing is individually prepared according to processing contents (type, composition ratio, film quality, film thickness, processing procedure, processing condition, and the like of film to be formed or removed) and stored in the memory 121c via an electric communication line or the external memory 123. Then, when the processing is started, it is preferable that the CPU 121a appropriately select an appropriate recipe from the plurality of recipes stored in the memory 121c according to the processing contents. As a result, films of various film types, composition ratios, film qualities, and film thicknesses can be formed with good reproducibility by one substrate processing apparatus, and appropriate processing can be performed for each case. In addition, a burden of an operator (an input load of a processing procedure, a processing condition, and the like) can be reduced, and the processing can be quickly started while an operation error is avoided.

The above-described recipe is not limited to be newly created, but may be prepared by, for example, changing the existing recipe already installed in the substrate processing apparatus. When changing the recipe, the changed recipe may be installed in the substrate processing apparatus through an electric communication line or a recording medium in which the recipe has been recorded. In addition, the existing recipe already installed in the substrate processing apparatus may be directly changed by operating the input/output device 122 included in the existing substrate processing apparatus.

### (4) Effects of Present Embodiment

According to the above-described embodiment, one or a plurality of effects described below can be obtained.
(a) When a batch processing apparatus having a substrate loading region with the maximum loading number of X (X≥3) is used and less than X large surface area substrates are loaded and processed, it is possible to flatten the density distribution of the large surface area substrates between the substrate loading regions by dispersedly loading the large surface area substrates across the substrate loading regions. As a result, the film thickness uniformity between the substrate surfaces can be improved.
(b) By setting the number of divisions into the substrate groups to be large within a range not exceeding the number of loadable slots, that is, setting the number of substrates in each substrate group small, it is possible to improve the film thickness surface uniformity in each substrate group.

In the above-described embodiment, an example has been described in which a film is formed by using the substrate processing apparatus including a hot-wall-type process furnace. The present disclosure is not limited to the above-described embodiment, and can also be suitably applied to a case where a film is formed by using the substrate processing apparatus including a cold-wall-type process furnace. Also in these cases, a processing procedure and processing condition can be, for example, similar to those in the above-described embodiment.

According to the present disclosure, in a case where a plurality of substrates is loaded in a boat and subjected to batch processing, uniformity of film characteristics of the plurality of substrates can be improved as compared with that of the related art. In addition, controllability of the film thickness of a film formed on the substrates can be improved.

In recent years, with high integration and three-dimensional structure of semiconductor devices, the surface area thereof has been continuously increased. In a semiconductor manufacturing process, a so-called loading effect such as a change in film thickness of a film formed on a substrate caused by the large surface area has become a large issue, and a thin film forming technique for eliminating the influence has been desired. As one of methods for meeting the demand, there is a method of alternately supplying a plurality of process gases to form a film.

A method of alternately supplying a plurality of process gases to form a film is an effective means for the loading effect. However, in a process in a batch processing apparatus in which a substrate is loaded on a boat and a plurality of substrates is simultaneously loaded in the boat and films are formed, the thickness of a film formed on a substrate varies between the substrates depending on the number of substrates loaded, and thus, it may be difficult to control the thickness.

An object of the present disclosure is to provide a substrate processing apparatus, a method of manufacturing a semiconductor device, and a program capable of improving uniformity of the film thicknesses of a plurality of substrates as compared with that of the related art, in a case where the plurality of substrates is loaded in a boat and subjected to a batch processing.

What is claimed is:

1. A substrate processing apparatus comprising:
a process container capable of accommodating a substrate holder that holds substrates;
a gas supplier that supplies a gas to the process container;
an exhauster that exhausts an atmosphere in the process container;
a transporter that transports the substrates; and
a controller configured to be capable of controlling the transporter to dispersedly load the substrates from a central portion of a first region in a case where a number X of the substrates is smaller than a maximum loading number Y of the substrate holder, and the substrate holder includes, at a central portion, the first region where the dispersion loading is performed.

2. The substrate processing apparatus according to claim 1, wherein
the controller is configured to be capable of setting a size of the first region based on the number X.

3. The substrate processing apparatus according to claim 1, wherein
the controller is configured to be capable of controlling the transporter to perform a dispersion loading from the central portion of the first region and change loading density toward one or both of an upper end side and a lower end side of the first region.

4. The substrate processing apparatus according to claim 1, wherein
the controller is configured to be capable of controlling the transporter to gradually change density of the dispersion loading.

5. The substrate processing apparatus according to claim 1, wherein
the controller is configured to be capable of controlling the transporter that makes density of the first region smaller than density of other regions.

6. The substrate processing apparatus according to claim 1, wherein
the controller sets an interval between the substrates in the first region based on the number X.

7. The substrate processing apparatus according to claim 1, wherein
the substrate holder includes, on an upper end side and a lower end side, a second region where the substrates are sequentially loaded, and
the controller is configured to be capable of controlling the transporter to sequentially load the substrates in the second region.

8. The substrate processing apparatus according to claim 7, wherein
the controller sets a ratio between the first region and the second region based on a relationship between the number X and the number Y.

9. The substrate processing apparatus according to claim 1, wherein
the controller is configured to be capable of controlling the transporter to dispose the substrates from an upper end side to a lower end side of the substrate holder.

10. The substrate processing apparatus according to claim 7 further comprising:
a first nozzle in which first supply holes through which a gas is supplied to the upper end side of the substrate holder; and
a second nozzle in which second supply holes through which a gas is supplied to the lower end side of the substrate holder, wherein
the second region outside the first region is provided at a position close to one of the first supply holes or the second supply holes.

11. The substrate processing apparatus according to claim 10, wherein
the gas supplier is configured to be capable of supplying an inert gas from one or both of the first nozzle and the second nozzle.

12. The substrate processing apparatus according to claim 10, wherein
the gas supplier is configured to be capable of supplying a process gas from one or both of the first nozzle and the second nozzle.

13. The substrate processing apparatus according to claim 12, wherein
the process gas is one or both of a raw material gas and a reaction gas.

14. The substrate processing apparatus according to claim 1, wherein
the substrates are product substrates, and
one or more dummy substrates are loaded between the product substrates in the first region where the dispersion loading is performed.

15. The substrate processing apparatus according to claim 14, wherein
the controller sets a number of the one or more dummy substrates according to a number of the product substrates to be loaded in the first region of the substrate holder.

16. The substrate processing apparatus according to claim 14, wherein
the controller sets the number of the dummy substrates sequentially loaded in the first region according to a number of the product substrates to be loaded in the substrate holder in the first region.

17. The substrate processing apparatus according to claim 14, wherein
the controller is configured to be capable of controlling the transporter to alternately load the product substrates and the dummy substrates in the first region.

18. The substrate processing apparatus according to claim 1, wherein
the controller is configured to set, in the substrate holder, a slot in which any of the substrates is not loaded in advance, and to be capable of controlling the transporter not to load any of the substrates in the slot regardless of the number of the substrates.

19. A method of manufacturing a semiconductor device, comprising:
dispersedly loading substrates from a central portion of a first region in a case where a number X of the substrates is smaller than a maximum loading number Y of a substrate holder, and the substrate holder includes, at the central portion, the first region where the dispersion loading is performed;
transporting, into a process container, the substrate holder in which the substrates are loaded; and
supplying a process gas into the process container and processing the process gas.

20. A non-transitory computer-readable recording medium recording a program for causing, by a computer, a substrate processing apparatus to execute:
dispersedly loading substrates from a central portion of a first region in a case where a number X of the substrates is smaller than a maximum loading number Y of a substrate holder, and the substrate holder includes, at the central portion, the first region where the dispersion loading is performed;
transporting, into a process container, the substrate holder in which the substrates are loaded; and
supplying a process gas into the process container and processing the process gas.
